(19) United States
(12) Patent Application Publication
(10) Pub. No.: US 2010/0032759 A1
(43) Pub. Date: Feb. 11, 2010

(54) SELF-ALIGNED SOI SCHOTTKY BODY TIE EMPLOYING SIDEWALL SILICIDATION

(75) Inventors: Leland Chang, New York, NY (US); Isaac Lauer, White Plains, NY (US); Jeffrey W. Sleight, Ridgefield, CT (US)

Correspondence Address: MICHAEL BUCHENHORNER, P.A., 8540 SW 83 STREET, SUITE 100, MIAMI, FL, 33143, US

(73) Assignee: INTERNATIONAL BUSINESS MACHINES CORPORATION, Armonk, NY (US)

(21) Appl. No.: 12/189,639

(22) Filed: Aug. 11, 2008

(51) Int. Cl. H01L 21/336; H01L 29/786

(52) U.S. Cl. 257/347; 438/299; 257/E21.415; 257/E29.295

(57) ABSTRACT

A self-aligned Silicon on Insulator (SOI) Schottky Body Tie structure includes: a source region comprising a silicide layer disposed on a top surface of the source region; a drain region comprising a silicide layer disposed on a top surface of the drain region; a gate region disposed above a channel formed by the drain and source regions; and a gate oxide layer disposed between the gate region and the channel formed by the drain and source regions, wherein when silicidation is performed on the diffusion region it forms a metal-silicon alloy contact such that the silicide layer extends into and directly touches the channel.

### CROSS-REFERENCE TO RELATED APPLICATIONS

None.

### STATEMENT REGARDING FEDERALLY SPONSORED-RESEARCH OR DEVELOPMENT

None.

### INCORPORATION BY REFERENCE OF MATERIAL SUBMITTED ON A COMPACT DISC

None.

### FIELD OF THE INVENTION

The invention disclosed broadly relates to the field of integrated circuits, and more particularly relates to a Self-aligned SOI Schottky Body Tie Employing Sidewall Silicidation.

### BACKGROUND OF THE INVENTION

In silicon-on-insulator (SOI) technologies, there are many cases where electrical contact to the normally floating body region is highly desirable. Among these cases include the mitigation of history effects in SOI and the enablement of low leakage SOI devices and/or high voltage SOI devices. There are many known solutions in the known art. Almost all of these solutions typically have substantial density and parasitic penalties and many are not self-aligned. Many of the solutions also consume a portion of the device's electrical width.

The formation of a dual-sided Schottky body tie was first described by Sleight & Mistry (IEEE International Electron Devices Meeting 1997). In Sleight & Mistry's work, the dual-sided Schottky body tie was formed by intentionally omitting dopant from a portion of the diffusion region. While effective, this approach results in a loss of device electrical width as well as poor gate control from low gate doping in the regions.

J. Cai et al. (IEEE International Electron Devices Meeting 2007) describe using a Schottky body contact where the diffusion implants are angled in a manner to expose the source silicide to the body. This approach has drawbacks with the masking required and groundrule considerations on the angle that may be employed.

Therefore, a need exists for an improved SOI technology to address the foregoing shortcomings.

### SUMMARY OF THE INVENTION

Briefly, according to an embodiment of the invention, a structure is used to form a dual sided Schottky body tied SOI transistor device. The structure is self-aligned, has no detrimental parasitics that can occur from the terminals, does not consume any of the device's electrical width, and does not require masking or special implants. The transistor includes the following: a source region with a silicide layer disposed on its top surface; a drain region with a silicide layer disposed on its top surface; a channel with a diffusion region formed between the source and drain regions, and a silicide layer extending into the diffusion region; a gate region disposed above the diffusion region; a metal deposition region that covers the sidewalls and top of the diffusion region; and a gate oxide layer disposed between the gate region and the diffusion region. The silicide layer extends beyond a depletion region of the transistor edge, forming a Schottky diode junction. If necessary, the position of the diffusion region relative to the silicide is reinforced through thermal activation. This can be accomplished by laser or a flash anneal process.

According to another embodiment of the present invention, a method for forming a silicon-on-insulator transistor device includes the steps or acts of: exposing the sidewalls of a diffusion region of the transistor using an intentional pull-down of its shall trench isolation dielectric; depositing metal on the device such that the sidewalls and top of the diffusion region are covered in metal; and performing silicidation on the diffusion region to form a metal-silicon alloy to act as a contact, such that the silicide layer extends into and directly touches the transistor channel.

### BRIEF DESCRIPTION OF THE DRAWINGS

To describe the foregoing and other exemplary purposes, aspects, and advantages, we use the following detailed description of an exemplary embodiment of the invention with reference to the drawings, in which:

FIG. 1 shows a schematic diagram of a dual-sided Schottky device, according to an embodiment of the present invention;

FIG. 2 shows a top view of the physical structure of a structure, according to an embodiment of the present invention;

FIG. 3a is a front view of the structure of the embodiment of FIG. 2, according to the known art;

FIG. 3b is a front view of a dual-sided Schottky body tied SOI device, according to an embodiment of the present invention;

FIG. 4 is a flow chart of a method of producing the structure of the above embodiment.

While the invention as claimed can be modified into alternative forms, specific embodiments thereof are shown by way of example in the drawings and will herein be described in detail. It should be understood, however, that the drawings and detailed description thereto are not intended to limit the invention to the particular form disclosed, but on the contrary, the intention is to cover all modifications, equivalents and alternatives falling within the scope of the present invention.

### DETAILED DESCRIPTION

We discuss a new structure used to form a dual-sided Schottky body tied SOI device. The structure is self-aligned, has no detrimental parasitics, does not consume any of the device's electrical width, and does not require masking or special implants. The key aspect of the new Schottky device is an intentional recess formed in the shallow trench isolation (STI) oxide portion of the device that extends past the silicide layer.

During the source/drain silicidation step, the silicide on the edge of the device will extend further, since there is a metal source both from the top and side. The diffusion junction is then placed so that it is extends past the silicide in the center of the device (normal diffusion to body junction), whereas the silicide extends past the junction of the device edges (Schottky junction). The required STI recess in unmasked (blanket wafer) and no transistor electrical width is consumed as there is no alteration of the gate or deep diffusion implant.

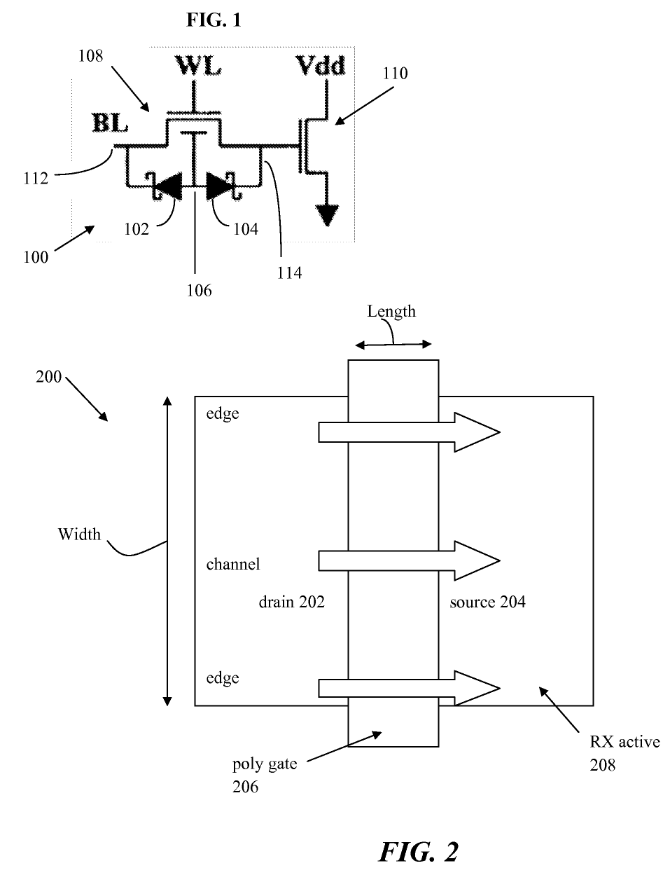

Referring now in specific detail to the drawings, and particularly FIG. 1, there is illustrated a schematic diagram of the dual-sided Schottky device 100, according to an embodiment of the present invention. The device comprises first 102 and second 104 Schottky devices coupled at their anodes 106 and having their respective cathodes coupled to the source 112 and drain 114 of a field effect transistor (FET) 108. A FET 110 has a drain coupled to Vdd (Voltage drain drain—positive operating voltage of a field effect semiconductor device) and a gate coupled to the drain 114 of FET transistor 108. In this embodiment the gate of FET transistor 108 represents the word line and its source 112 represents the bit line.

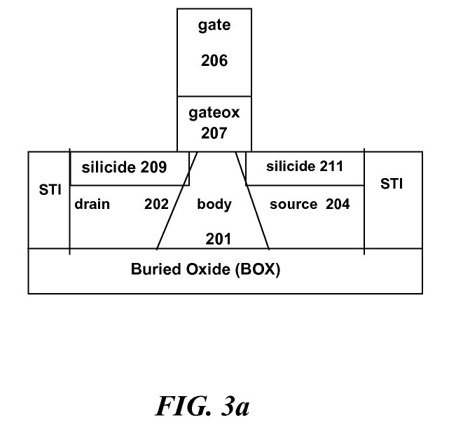

Referring to FIG. 2 there is shown a top view of the physical structure of device 200. The central region 206 operates as a poly Silicon gate 206. The drain 202 is shown on the left and the source 204 on the right. The arrows indicate the flow of current. The center arrow depicts the current flow from drain 202 to source 204 in an Nfet (negative channel field effect transistor), assuming positive voltage drops (Vds). Active region 208 is shown to the right. Since there is no doping alteration, there is no current loss.

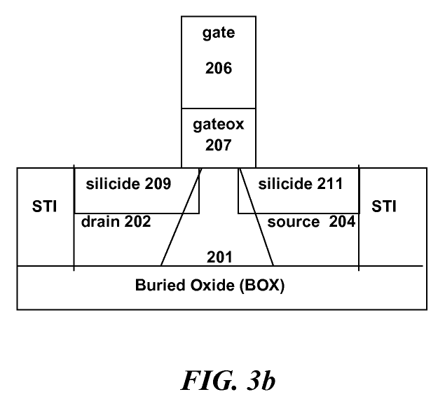

FIG. 3a shows a front view of the structure of the embodiment of FIG. 2. The structure comprises the drain 202, the source 204 and a gate 206. In addition, a first layer 209 of silicide is deposited over the drain 202 and a second layer 211 of silicide is deposited over the source 204. A layer 207 of gate oxide is located between the gate 206 and the drain to source channel. FIG. 3a shows a standard FET region in the middle of the FET. FIG. 3b shows the same structure, but with the silicide 209 211 encroaching past the diffusion junction, directly touching the SOI body 201. The Silicide at the transistor edge extends beyond the depletion region, creating a Schottky diode junction.

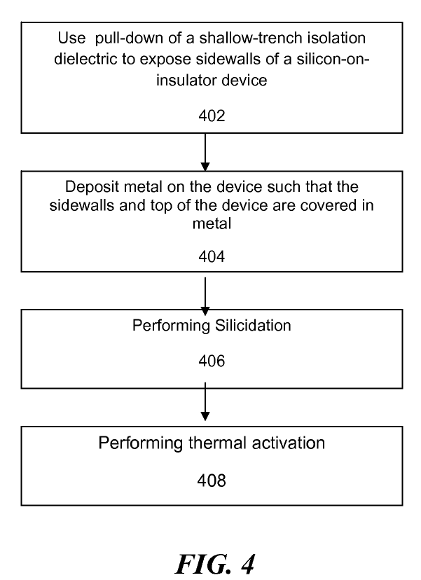

Referring to FIG. 4 there is shown a flow chart 400 of a method of producing the structure of the above embodiment. In particular, FIG. 4 is a flow chart illustrating a method for producing a Self-aligned SOI Schottky Body Tie Employing Sidewall Silicidation according to an embodiment of the invention. The input to the method is an SOI device such as the one shown in FIG. 1.

Receiving the device of FIG. 1 as input, the method proceeds at step 402 by exposing the sidewalls in the trench of the SOI device using an intentional pull-down of the shallow trench isolation (STI) dielectric. The sidewalls are exposed to a free surface (such as air) until there is no material, such as oxide, in contact with the sidewalls.

Following this, in step 404 a metal is deposited such that both the sidewall and top of the device diffusion region is covered in metal. The metal can be, but is not limited to, any one of the following: Nickel, Cobalt, Nickel and Platinum, and Erbium, Ytterbium. Next in step 406 the silicidation step is performed. Silicidation is an annealing process that results in the formation of a metal-Si alloy (silicide) to act as a contact. A silicide is an alloy of silicon and metals. During the silicidation step, the device diffusion region encroaches closer to the channel (depletion region).

Lastly, in step 408 thermal activation techniques (such as laser and flash anneal) may be performed if necessary to reinforce the position of the diffusion region relative to the silicide so that at the end of the process, the silicide layer extends past the junction of the device edges.

Therefore, while there has been described what is presently considered to be the preferred embodiment, it will understood by those skilled in the art that other modifications can be made within the spirit of the invention. The above description of an embodiment is not intended to be exhaustive or limiting in scope. The embodiment, as described, was chosen in order to explain the principles of the invention, show its practical application, and enable those with ordinary skill in the art to understand how to make and use the invention. It should be understood that the invention is not limited to the embodiment described above, but rather should be interpreted within the full meaning and scope of the appended claims.

We claim:

1. A method comprising steps of:
performing an intentional pull-down of a shallow trench isolation dielectric of a diffusion region in a silicon on insulator device in order to expose sidewalls of the diffusion region such that said sidewalls are not in contact with any solid material, the device comprising:
a source region comprising a silicide layer disposed on a top surface of the source region;
a drain region comprising the silicide layer disposed on a top surface of the drain region;
a channel comprising a diffusion region formed between the drain and source regions;
a gate region disposed above the diffusion region; and
a gate oxide layer disposed between the gate region and the diffusion region;
depositing metal on the device such that the sidewalls and top of the diffusion region are covered in metal; and
performing silicidation on the diffusion region to form a metal-silicon alloy to act as a contact, such that the silicide layer extends into and directly touches the channel.

2. The method of claim 1 further comprising performing thermal activation to reinforce a position of the diffusion region relative to the silicide.

3. The method of claim 2 further comprising performing the thermal activation with a laser.

4. The method of claim 2 further comprising performing the thermal activation with a flash anneal.

5. The method of claim 1 further comprising performing the metal deposition with Nickel.

6. The method of claim 1 further comprising performing the metal deposition with Cobalt.

7. The method of claim 1 further comprising performing the metal deposition with Nickel and Platinum.

8. The method of claim 1 further comprising performing the metal deposition with Erbium.

9. The method of claim 1 further comprising performing the metal deposition with Ytterbium.

10. A self-aligned Silicon on Insulator transistor structure comprising:
a source region comprising a silicide layer disposed on a top surface of said source region;
a drain region comprising the silicide layer disposed on a top surface of the drain region;
a channel comprising a diffusion region formed between the drain and source regions, wherein the silicide layer extends into the diffusion region, and wherein the diffusion region comprises a top and sidewalls wherein said sidewalls of the diffusion region are exposed as a result of an intentional pull-down of its shall trench isolation dielectric, such that said sidewalls are not in contact with any solid material;
a gate region disposed above the diffusion region;
a metal deposition region covering the exposed sidewalls and the top of the diffusion region; and
a gate oxide layer disposed between the gate region and the diffusion region.

11. The structure of claim 10 wherein the silicide is at an edge of the transistor structure and extends beyond a depletion region, forming a Schottky diode junction.

12. The structure of claim 10 wherein the diffusion region comprises a thermally activated reinforcement relative to the silicide.

13. The structure of claim 12 wherein the thermally activated reinforcement comprises thermal activation by laser.

14. The structure of claim 12 wherein the thermally activated reinforcement comprises thermal activation by a flash anneal process.

15. The structure of claim 10 wherein the metal deposition region comprises Nickel.

16. The structure of claim 10 wherein the metal deposition region comprises Cobalt.

17. The structure of claim 10 wherein the metal deposition region comprises Nickel and Platinum.

18. The structure of claim 10 wherein the metal deposition region comprises Erbium.

19. The structure of claim 10 wherein the metal deposition region comprises Ytterbium.
